(19) United States
(12) Patent Application Publication
(10) Pub. No.: US 2022/0043032 A1
(43) Pub. Date: Feb. 10, 2022

(54) NON-INVASIVE VOLTAGE SENSOR FOR POLYPHASE CABLES

(71) Applicant: Massachusetts Institute of Technology, Cambridge, MA (US)

(72) Inventors: Steven B. LEEB, Belmont, MA (US); Katherine Camenzind, Cambridge, MA (US); Daisy Green, Cambridge, MA (US); Lukasz Huchel, Cambridge, MA (US); Thomas Krause, Cambridge, MA (US)

(21) Appl. No.: 17/397,178

(22) Filed: Aug. 9, 2021

Related U.S. Application Data
(60) Provisional application No. 63/063,553, filed on Aug. 10, 2020.

(51) Int. Cl. G01R 15/16; G01R 27/26

(52) U.S. Cl. CPC G01R 15/16; G01R 27/2605

(57) ABSTRACT

Systems and techniques for non-intrusive measurement of a cable with multiple conductors include plates that form capacitive couplings with the conductors within the cable. The plates can be placed outside the cable, adjacent to one of the conductors within the cable. The capacitive couplings allow AC voltages within the cable to create currents that flow between the plates. These currents are measured and used to calculate the line voltages on the conductors within the cable.

### RELATED APPLICATIONS

This application claims the benefit of U.S. Provisional Patent Application No. 63/063,553 (filed Aug. 10, 2020), which is incorporated here by reference in its entirety.

### FIELD

This application generally relates to systems and techniques for monitoring voltages in cables with multiple conductors and, more particularly, to systems and techniques for non-invasive monitoring of voltages in cables with multiple conductors.

### BACKGROUND

Multi-conductor cables, for example polyphase cables for electrical power delivery, are used in many applications. Three-phase power, for example, is a common method used in electrical grids to transfer power from power stations to power consumers. It is also used in many manufacturing environments.

Problems that occur in a polyphase power delivery system can be costly and time-consuming to troubleshoot. Typically, circuits that monitor or sense the voltage in a multi-conductor cable require a direct electrical connection with one or more of the conductors within the cable. Since these cables are typically insulated, this means that the monitoring circuit must be connected at an electrical junction at an end of the cable. Access to such an electrical junction which may be difficult to obtain. Alternatively, the cable insulation can be cut or otherwise removed to provide an access point where the monitoring circuit can be connected to the conductors. This may require the cable to be repaired or replaced after the voltage measurements are taken.

Also, before the junction is accessed or the insulation cut by a technician and the monitor circuit is attached, power to the cable may need to be shut off to ensure the technician's safety. In the case of an electrical grid, this can cause portions of the grid to go offline. In the case of a manufacturing environment, shutting off the power to a cable could potentially stop a production line.

### SUMMARY

In accordance with the concepts, systems, circuits and techniques described herein, to address some or all these problems, a non-invasive voltage monitoring circuit may be placed or otherwise disposed around an outside surface of a polyphase cable to sense the voltages of the conductors within the polyphase cable.

In an embodiment, a system for non-intrusive line voltage monitoring of a cable with multiple conductors includes a plurality of electrically conductive plates disposed adjacent an electrical conductor within the polyphase cable. The conductive plates are disposed such each plate is primarily capacitively coupled to a single electrical conductor within the polyphase cable while at the same time being electrically isolated from other electrical conductors within the polyphase cable. In embodiments, a high degree of capacitive coupling (and ideally, a maximum capacitive coupling) exists between a respective one of the plates and a respective one of the electrical conductors. At the same time, the plates are also disposed such that there is a low degree of capacitive coupling (and ideally, minimal capacitive coupling or even total electrical isolation) between the plate and other ones of the multiple conductors. Thus, in preferred embodiments, there is strong capacitive coupling characteristic between a single one of the plates and single one of the multiple electrical conductors while (at the same time) the plates are (ideally) isolated from or have a minimal amount of a capacitive coupling to all other ones of the multiple conductors. The overall arrangement of conductive plates and conductors (i.e. the location of the plates relative the conductors) is thus selected to (ideally) maximize capacitive coupling between each plate and an associated conductor while (ideally) minimizing coupling between each plate and other conductors. The system includes a circuit to determine the voltage of at least one of the electrical conductors by measuring currents flowing between at least two of the conductive plates.

In another embodiment, a method for non-intrusive line voltage monitoring of a cable with multiple conductors includes positioning a plurality of conductive plates around the cable. Each conductive plate is placed or otherwise disposed adjacent an electrical conductor within the cable to result in a strong (and ideally, a maximum) a capacitive coupling between a respective conductive plate and an electrical conductor and minimize a capacitive coupling between the respective conductive plate and other electrical conductors within the polyphase cable. In embodiments, a strong a capacitive coupling results between a respective conductive plate and a closest (i.e., the physically closest) electrical conductor. One or more current measurement circuits is configured to detect and/or measure currents flowing between pairs of the conductive plates. A line voltage for each electrical conductor within the cable may be determined (e.g. calculated, derived or otherwise determined such as with a lookup table) based upon the currents flowing between the pairs of the conductive plates.

### BRIEF DESCRIPTION OF THE DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more exemplary embodiments. Accordingly, the figures are not intended to limit the scope of the invention. Like numbers in the figures denote like elements.

FIG. 1 is a diagram of a polyphase cable.

FIG. 2 is a block diagram of a system for non-invasive sensing of line voltage in a cable.

FIG. 3 is a cross-sectional diagram of polyphase cable with conductive plates placed around the cable.

FIG. 4 is a circuit model of the polyphase cable and plates of FIG. 2.

FIG. 5A is a circuit diagram of a “delta circuit” with transimpedance amplifier (“TIA”) circuits between pairs of conductive plates.

FIG. 5B is a circuit model of the delta circuit of FIG. 4A.

FIG. 6 is a circuit diagram of a transimpedance amplifier circuit.

FIG. 7 is a diagram of an impulse response of a finite impulse response (“FIR”) filter that may be used as an integrator circuit.

FIG. 8A and FIG. 8B are cross sectional diagrams of multi-conductor cables with conductive plates placed to detect voltage.

FIG. 9 is a graph of line voltage of a three-phase electrical power cable as measured by a non-intrusive line voltage monitoring system.

FIG. 10 is a flowchart of a process for calibration and measurement by a non-intrusive line voltage monitoring system.

### DETAILED DESCRIPTION

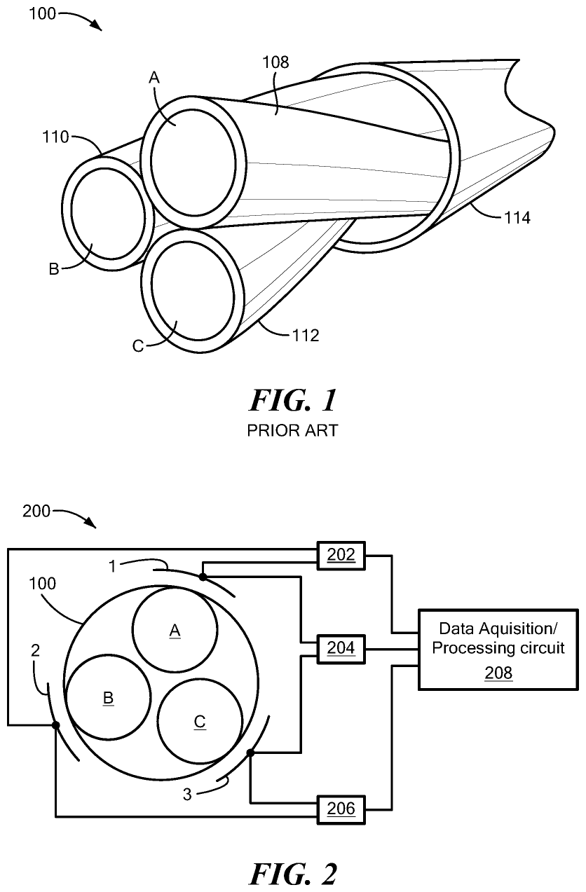

FIG. 1 is a diagram of a cable 100 comprising multiple conductive wires (or more simply “conductors,” “wires” or “lines”) with here three (3) conductors (designated A, B, and C in FIG. 1) being shown. Each conductor A-C has an insulating material (e.g. a jacket or sheath) 108, 110, 112 disposed thereover to electrically isolate the conductors from one another. Another insulating jacket or sheath 114 is disposed about the three conductors to hold or otherwise secure them together and to electrically isolate and protect them from the external environment.

In this example, the cable 100 has three conductive wires and may be a three-phase power cable. In other examples, the cable 100 may have two conductive wires or more than three conductive wires (e.g. four, five or six conductive wires) and may carry any type of AC electrical signals. For example, a mix of phase or “hot” wires and ground wires might be present in the same cable.

As noted above, typically, to measure the line voltage of each conductive wire, the measurement tool (e.g. a voltmeter, oscilloscope, data analyzer, or the like) must be electrically coupled to the conductor A, B, and/or C that is carrying the voltage. This requires either cutting (or otherwise removing some or all of) the insulating sheaths to create a hole (or holes) through which a probe (or probes) can be inserted to make contact with the conductive wires, or coupling the probe to an end-point of the cable where the conductive wires connect to a junction box or other housing.

Referring to FIG. 2, a system 200 for non-intrusively monitoring the line voltage of a cable 100′ (which may be the same as or similar to cable 100 in FIG. 1) includes a plurality of electrically conductive plates (such as conductive plates 1, 2, and 3) that are disposed or otherwise placed around the cable 100′. The conductive plates may be formed from a conductive material (e.g. a conductive metal) such as copper or other conductive material that can form a capacitive coupling with the conductors in the cable. Alternatively, plates 1, 2, 3 may be provided from a non-conductive material and plated with a conductive material. As shown, the conductive plates may have a shape selected to substantially match the contour of the outer surface of the cable 100′ over which the plate is disposed. In the example embodiment of FIG. 2, the cable 100′ has a round shape (e.g. a circular cross-sectional shape) and thus at least a surface of plates 1, 2, 3 proximate a surface of the cable is provided having a curved shape. In other embodiments, the plates may be flat (i.e. planar) or may have other various shapes that allow the formation of a capacitive coupling. In some embodiments, it may be desirable for a plate surface to match or substantially match the shape of the conductor within the cable (e.g. it may be desirable for a surface of plate 1 to substantially match the shape of conductor A. It may also be desirable, for a surface plate, e.g., plate 1, to substantially match part of the shape of the outer cable over conductor A.

It may be desirable for a coupling characteristic (e.g. a capacitive coupling characteristic) between one plate and a respective conductor (e.g. plate 1 and conductor A) to be substantially the same as the same coupling characteristic between the other plates and their respective conductive cables (e.g. a capacitive coupling characteristic between plate 1 and conductor A substantially matches (and ideally matches) a capacitive coupling characteristic between plate 2 and conductor B and a capacitive coupling characteristic between plate 3 and conductor C). Thus, in embodiments in which the conductors of a cable (e.g. conductors A, B, C in FIG. 2) are substantially the same size and shape as each other (and ideally are the same size and shape as each other), all capacitive plates (e.g. plates 1, 2, 3 and FIG. 2) may be substantially the same size and shape as each other.

On the other hand, if the conductive cables are of different sizes, the capacitance of the coupling between the cable and the plate may be different. In this case, a plates having different sizes and/or shapes may be used so as to result in substantially the same capacitive coupling characteristics. Alternatively, in embodiments it may be desirable to allow different capacitive coupling characteristics between respective pairs of plates and conductors but it would be desirable (and in some instances, even necessary) to know the capacitive coupling characteristic of each respective pair of plates and conductors such that voltages on each conductor may be determined in a manner which is the same as or similar to that described herein.

In general, the size and shape of the individual plates may be selected so that the capacitance of the capacitive coupling between the plate and the nearest conductive cable is substantially the same as the capacitance capacitive coupling between the other plates and their respective nearest conductive cable.

Each plate is positioned or otherwise disposed on or about an outside surface of the cable (e.g. on a surface of insulative jacket 114 in FIG. 1) adjacent or proximate a respective conductor to maximize the capacitance (e.g. the capacitive coupling characteristic) between the conductive plate and the nearest conductor, and to reduce (and ideally minimize) the capacitance of the capacitive coupling between the conductive plate and the other conductors within the cable 100. This concept will be discussed below in greater detail.

The system also includes current measurement circuits 202, 204, and 206 configured to measure a current flowing between pairs of the conductive plates. These currents may be referred to as “branch currents.” For example, current measurement circuit 202 measures the current flowing between plates 1 and 2, current measurement circuit 204 measure the current flowing between plates 1 and 3, and current measurement circuit 206 measures the current flowing between plates 2 and 3.

A data acquisition and processing circuit 208 is coupled to the current measurement circuits 202, 204, and 206. In embodiments, circuit 208 may be a general-purpose processor or microprocessor executing software stored in a non-transitory physical medium (i.e. a memory). In other embodiments, circuit 208 may be custom circuit designed to acquire and process the current measurements from the current measurement circuits 202, 204, and 206. Whatever the form of circuit 208, it may be configured to process the current measurements from the current measurement circuits, to measure and reconstruct the line voltages on the conductors A, B, and C without the need for invasive probing, and to provide one or more output signals representing the measured voltages.

For ease of illustration, the system 200 will be shown as a system for measuring a cable with three conductors throughout this document. However, after reading the description provided herein, one of ordinary skill in the art will readily understand the manner in which system 100 may be adapted to operate with cables having more than three conductors by adding additional conductive plates and current measurement circuits between the plates. For example, a system for measuring a four voltages in a four-wire cable may include four plates. The four-wire system may require six current measurement circuit to measure the current between each possible pair of plates. Likewise, a system for measuring five voltages in a five-wire cable may include five conductive plates and ten current measurement circuits to measure the current between each possible pair of plates. In embodiments, techniques may be used to reduce the number of current measurement circuits needed so that a current measurement circuit is not required between each and every possible pair of plates. However, these techniques are outside the scope of this disclosure.

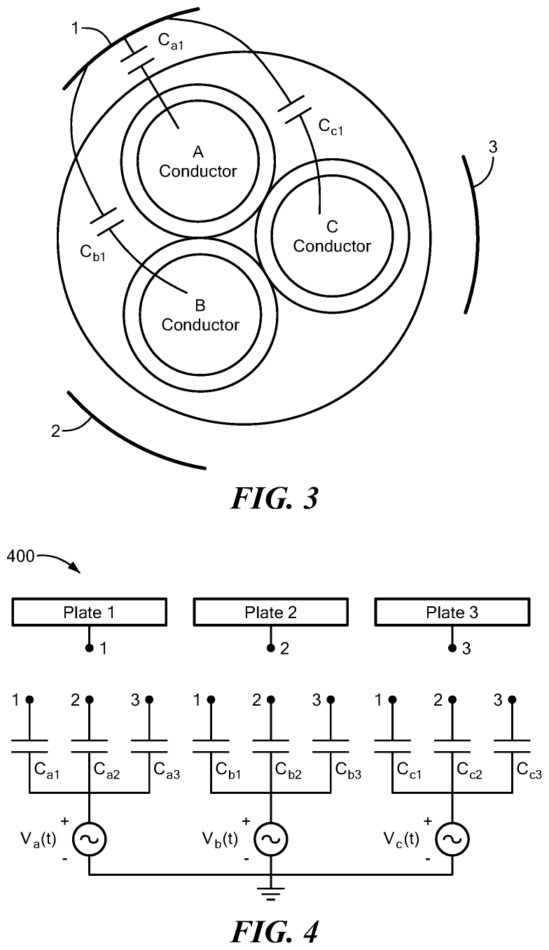

Referring to FIG. 3, the cable 100 is shown again in cross sectional view with conductive plates 1, 2, and 3 positioned around the outside of the cable. As shown, a capacitive coupling Cₐ₁ is formed between conductive plate 1 and conductor A. If this were the only capacitive coupling that was formed, it may be relatively easy to use the capacitive coupling Cₐ₁ to monitor the line voltage of conductor A. However, there are other capacitive couplings formed such as a capacitive coupling between plate 1 and conductor B (i.e. capacitive coupling C_{b1}) and capacitive coupling between plate 1 and conductor C (i.e. capacitive coupling C_{c1}). These other couplings are referred to herein as “parasitic capacitive couplings” (or “parasitic capacitances”) between the conducive plate 1 and the non-nearest conductive wires (i.e. conductive wires B and C). Such parasitic capacitances interfere with measurement of the line voltage of conductor A using plate 1, thereby making it difficult or impossible to accurately measure the line voltage of conductor A using only the capacitive coupling between plate 1 and conductor A.

In this embodiment, plate 1 is placed in a position to ideally maximize the capacitance of capacitive coupling Cₐ₁ and ideally minimize the capacitance of capacitive couplings C_{b1} and C_{c1}. Since capacitance is inversely proportional to the distance between plate 1 and the wires, this can be accomplished, for example, by positioning plate 1 as close as possible to conductor A so that the distance between plate 1 and conductor A is reduced (and ideally minimized), and further away from conductors B and C so the distances between plate 1 and conductors B and C are increased (and ideally maximized). In this example, each distance might be measured from the center of the plate surface to the center of each conductor.

Although not shown in FIG. 2, I should be appreciated that similar capacitive couplings may be formed between plate 2 and the conductive wires, and between plate 3 and the conductive wires.

In FIG. 4, the circuit 400 provides a model of the capacitive couplings between plates 1, 2, and 3 and the conductive wires A, B, and C. Assuming that the voltage (e.g. a time varying voltage such as an AC voltage) on conductor A is driven by voltage source Vₐ(t), the voltage on conductor B is driven by voltage source V_{b}(t), and voltage on conductor C is driven by voltage source V_{c}(t), the model circuit 400 provides an illustration of the capacitive interference between the plates and conductive wires. For example, as mentioned above, a capacitance exists between plate 1 and conductor A (illustrated as capacitor Cₐ₁ in FIG. 4) and a capacitance also exists between plate 1 and conductors B and C (illustrates as capacitors C_{b1} C_{c1} in FIG. 4). Thus, the voltage on plate 1 is affected not only by voltage source Vₐ(t), but also by sources V_{b}(t) and V_{c}(t). Following the same circuit logic, the voltage on plate 2 is affected not only by voltage source V_{b}(t), but also by voltage source Vₐ(t) and V_{c}(t), and the voltage on plate 3 is affected not only by voltage source V_{c}(t), but also by voltages source Vₐ(t) and V_{b}(t). Thus, to achieve an accurate voltage measurement, the system 200 (FIG. 2) must compensate for the parasitic capacitances between the plates and the conductive cables, and for the corresponding parasitic voltage changes on the plates due to the parasitic capacitive couplings.

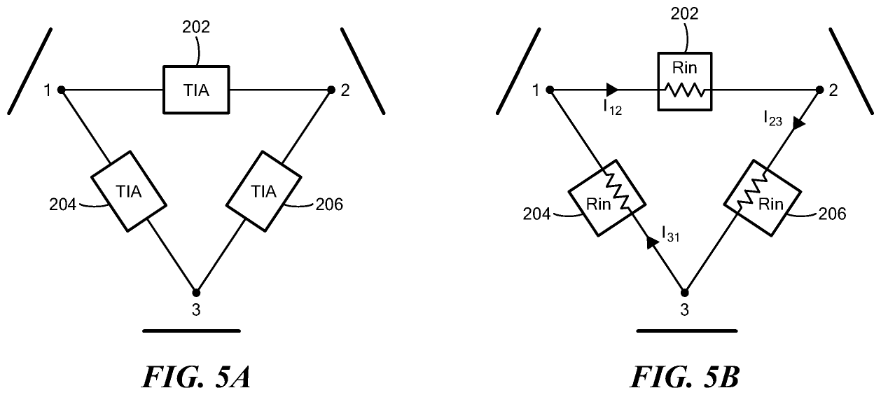

Referring to FIGS. 5A and 5B, to compensate for the parasitic capacitive couplings, the system 200 includes current measurement circuits 202, 204, and 206. As shown in FIG. 5A (and FIG. 2), current measurement circuit 202 is coupled between plates 1 and 2 to measure current flowing between plates 1 and 2, current measurement circuit 204 is coupled between plates 1 and 3 to measure current flowing between plates 1 and 3, and current measurement circuit 206 is coupled between plates 2 and 3 to measure current flowing between plates 2 and 3. As shown in FIG. 5B, the current measurement circuits 202, 204, and 206 can be modeled as resistors having a resistance characteristic which allows current (i.e. current driven by the capacitive couplings between the plates) to flow between the plates. In practical systems, the resistors in the model are provided having a resistance value which is relatively small. The current measurement circuits can measure the current flowing though the resistor and convert it to a voltage for processing. The net capacitance Cₙₑₜ arising from each conductor wire is approximately Cₐ₁+Cₐ₂+Cₐ₃ as shown in FIG. 4. It is typically convenient to have the RC time constant Rᵢₙ*Cₙₑₜ associated with the measurement circuit to be substantially less than one, although other ranges are possible.

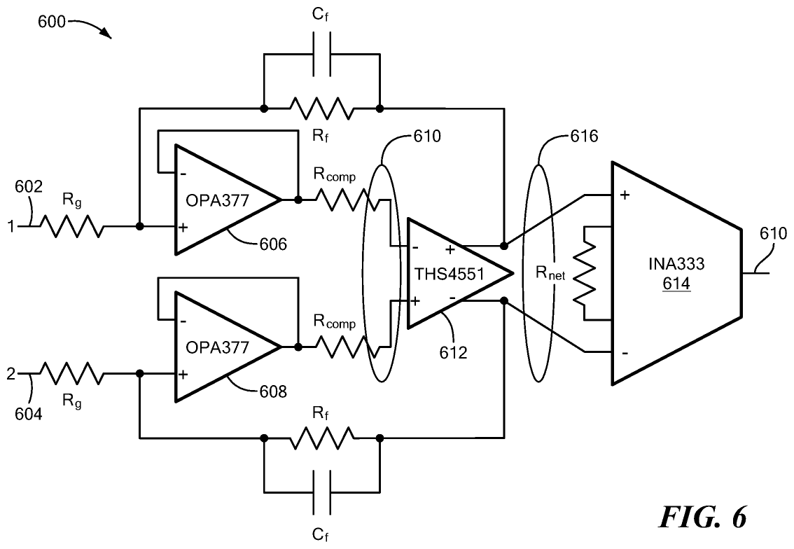

Referring to FIG. 6, current measurement circuit 600 may be the same as or similar to current measurement circuits 202, 204, and 206. In embodiments, current measurement circuit 600 may comprise or correspond to a transimpedance amplifier circuit that converts the measured current into a voltage output. Circuit 600 may also comprise a fully differential amplifier, meaning that it has a differential input and a differential output. However, in other embodiments, circuit 600 may be (or may include) an amplifier with a single-ended output.

Fully differential, transimpedance amplifiers may be useful because of the small currents between the plates. Because transimpedance amplifiers convert current to voltage, they have a gain with units of Ohms, i.e. the output voltage divided by input current. Thus, the amplifier may act as a virtual short circuit between the plates (or a circuit with very small resistance), with input resistance equal to 2Rg.

Circuit 600 may also include unity gain buffers 606 and 608 (implemented in this example as operational amplifiers) that buffer the differential input signal to produce a differential voltage signal 610 that represents the current flowing from input node 602 to input node 604 (or vice versa). The unity gain buffers 606 and 608 act to limit the effect of input bias current on the sensed signal. Limiting the input bias current avoids distortion of the current flowing in the measurement circuit between the sensing plates.

Differential voltage signal 610 is fed into a fully differential amplifier 612, which amplifies signal 610 and produces amplified signal 616. The unity gain buffers 606 and 608, and the fully differential amplifier 612, provide the fully differential transimpedance amplification function of circuit 600. An optional instrumentation amplifier 614 may be included to convert the differential output signal 616 of amplifier 612 to single-ended output signal 618.

Referring again to FIG. 2, the output signals from the current measurement circuits 202, 204, and 206 are fed into data acquisition and processing circuit 208, which uses those signals to calculate the line voltage of conductive wires A, B, and C. To calculate the line voltages, circuit 208 may effectively process the signals in a manner that isolates the desired capacitive couplings while minimizing the effect of the parasitic capacitive couplings described above.

Referring again to FIGS. 5A and 5B, the current at nodes 1, 2, and 3 (e.g. plates 1, 2, and 3) can be represented in the equation(s):

$$\{ \begin{matrix}{I}_{{C}_{a 1} +} {I}_{{C}_{b 1} +} {I}_{{C}_{b 1} +} {I}_{31} - {I}_{12} = 0 \\ {I}_{{C}_{a 2} +} {I}_{{C}_{b 2} +} {I}_{{C}_{c 2} +} {I}_{12} - {I}_{23} = 0 \\ {I}_{{C}_{a 3} +} {I}_{{C}_{b 3} +} {I}_{{C}_{c 3} +} {I}_{23} - {I}_{31} = 0\end{matrix} \qquad ( 1 )$$

Where I_{C}_{_{xy}} is the capacitor current between conductive wire x and conductive plate y, and Iⱼₖ is the branch current between plates j and k. The currents in equation 1 can be expressed in matrix form Ax=b, as shown below in equation (2), where A is the system (conductance) matrix, x are the unknown node voltages, and b are terms of the voltages of the sources driving the voltage on the conductive wires A, B, and C.

$$x = [ \begin{matrix}{V}_{1} \\ {V}_{2} \\ {V}_{3}\end{matrix} ] \\ b = [ \begin{matrix}s ( {C}_{a 1} {V}_{a} + {C}_{b 1} {V}_{b} + {C}_{c 1} {V}_{c} ) \\ s ( {C}_{a 2} {V}_{a} + {C}_{b 2} {V}_{b} + {C}_{c 2} {V}_{c} ) \\ s ( {C}_{a 3} {V}_{a} + {C}_{b 3} {V}_{b} + {C}_{c 3} {V}_{c} )\end{matrix} ] \\ A = [ \begin{matrix}s ( {C}_{a 1} + {C}_{b 1} + {C}_{c 1} ) + \frac{2}{{R}_{in}} & \frac{- 1}{{R}_{in}} & \frac{- 1}{{R}_{in}} \\ \frac{- 1}{{R}_{in}} & s ( {C}_{a 2} + {C}_{b 2} + {C}_{c 2} ) + \frac{2}{{R}_{in}} & \frac{- 1}{{R}_{in}} \\ \frac{- 1}{{R}_{in}} & \frac{- 1}{{R}_{in}} & s ( {C}_{a 3} + {C}_{b 3} + {C}_{c 3} ) + \frac{2}{{R}_{in}}\end{matrix} ] \qquad ( 2 )$$

The current measurement circuits 202, 204, and 206 provide measurements of the current flowing between the plates. Therefore, the currents between the plates can be expressed as:

$$[ \begin{matrix}{I}_{12} \\ {I}_{23} \\ {I}_{31}\end{matrix} ] = [ \begin{matrix}{H}_{11} & {H}_{12} & {H}_{13} \\ {H}_{21} & {H}_{22} & {H}_{23} \\ {H}_{31} & {H}_{32} & {H}_{33}\end{matrix} ] [ \begin{matrix}{V}_{a b} \\ {V}_{b c} \\ {V}_{c a}\end{matrix} ] \qquad ( 3 )$$

where the matrix H is a transfer function matrix and Vₘₙ is the line-to-line (differential) voltage between conductive wires m and n. Again, and Iⱼₖ is the branch current between plates j and k. Assuming that the capacitances between the plates and the conductive wires are balanced, the terms of the H matrix in equation (3) can be approximated as:

$${H}_{11} = {H}_{22} = {H}_{33} = \frac{( {C}_{p} - {C}_{s} ) s}{( {C}_{p} + 2 {C}_{s} ) {R}_{i n} + 3} \qquad ( 4 )$$

where Cₚ is the value of the primary capacitance between nearest conductive plates and conductive wires (e.g. between plate 1 and wire A), and Cₛ is the value of the secondary capacitance (i.e. the parasitic capacitances) between the conductive plate and the other conductive wires (e.g. between plate 1 and wire B, or between plate 1 and wire C). After simplification, the other terms in the H matrix are zero or close enough to be zero so that they can be ignored, resulting in the matrix equation:

$$[ \begin{matrix}{I}_{12} \\ {I}_{23} \\ {I}_{31}\end{matrix} ] = [ \begin{matrix}\frac{( {C}_{p} - {C}_{s} ) s}{( {C}_{p} + 2 {C}_{s} ) {R}_{i n} + 3} & 0 & 0 \\ 0 & \frac{( {C}_{p} - {C}_{s} ) s}{( {C}_{p} + 2 {C}_{s} ) {R}_{i n} + 3} & 0 \\ 0 & 0 & \frac{( {C}_{p} - {C}_{s} ) s}{( {C}_{p} + 2 {C}_{s} ) {R}_{i n} + 3}\end{matrix} ] [ \begin{matrix}{V}_{a b} \\ {V}_{b c} \\ {V}_{c a}\end{matrix} ] \qquad ( 5 )$$

Thus, because the values I₁₂, I₂₃, and I₃₁ are measured and known, and because the values (or at least approximations of the values) of H₁₁, H₂₂, and H₃₃ are known, the data acquisition and processing circuit 208 can solve for and provide values for the differential voltages Vₘₙ between the conductive wires A, B, and C.

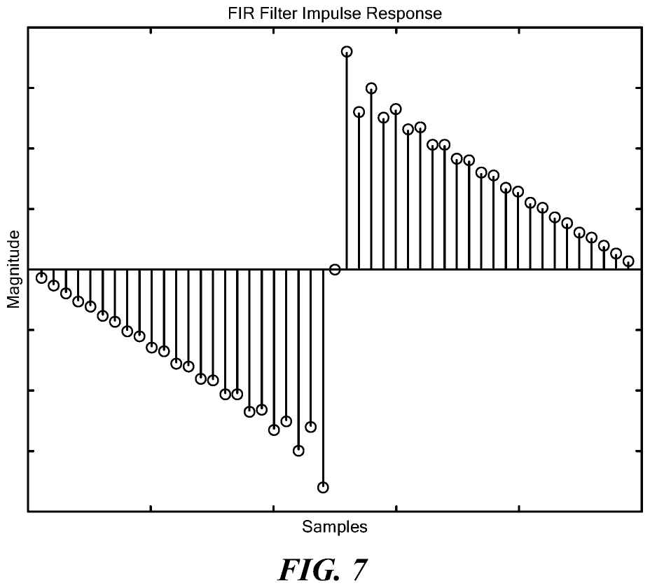

Referring to FIG. 7, to convert the differential voltages Vₘₙ into line voltages for each line, the data acquisition and processing circuit 208 may implement an integration function to integrate the sensor outputs. Branch currents between the plates are caused by capacitive coupling between the plates and the conductive wires, as described above. Thus, the branch currents between the plates are scaled versions of the derivatives of the line-to-line voltages, and the line-to-line voltages Vₘₙ can be viewed as differential voltages. Thus, to reconstruct the voltages, an integrator is applied to the branch currents. In embodiments, an FIR filter may be used as the integration function. The graph 700 illustrates an input response to an FIR filter that approximates an integration function, and thus may be used by data acquisition and processing circuit 208 to perform the integration. This FIR filter is applied to the output of each transimpedance amplifier of the type shown in FIG. 6. That is, the output voltage 610 in FIG. 6, which represents a sensed current between the plates, is integrated by the FIR filter.

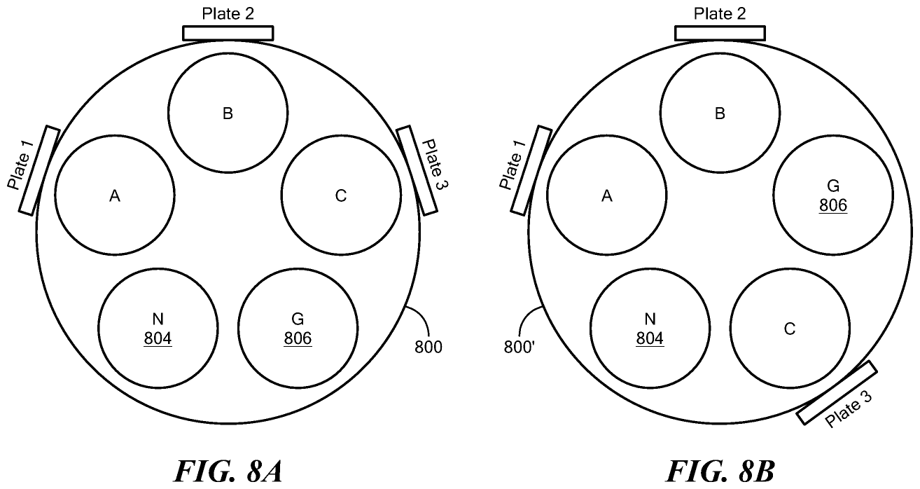

Referring to FIGS. 8A and 8B, the system may be used to measure line voltages of three-phase cables that have additional conductive wires within the cable. Cables 802 and 802′ are shown with five conductive wires. Like cable 100, these cables include the three phase wires A, B, and C. Unlike cable 100, these cables also include a neutral wire 804 and a ground wire 806.

The wires within the cable may be physically arranged in different arrangements. In cable 800, the phase wires A, B, and C are adjacent to each other. However, in cable 800′, the phase wires A and B are adjacent to each other, but phase wire C is adjacent to the neutral 804 and ground 806 wires.

In each case the plates should be placed so that they are as near as possible to a respective conductive wire that is carrying a voltage to be measured. As noted above, each plate should be placed so that the distance between the plate and its respective conductive wires in minimized, while the distance between the plate and the other conductive wires is maximized. Therefore, it may be beneficial to know the geometry of the cable 800 and the conductive wires prior to placement so that the cables can be placed around the cable in the appropriate position.

To assist in placing the plates, a plate housing (not shown) that holds the plates in place can be fixed around the cable. The housing may be configured to hold the plates in a fixed physical position with respect to each other. The housing may also fix the plates in a position that matches the geometry cable geometry.

Different housings may be used for different cable geometries. For example, a housing that matches cable 800 may be configured to hold the plates in a fixed position adjacent to each because the conductive wires A, B, and C, are arranged adjacent to each other. Another housing that matches cable 800′ may hold the plates in a fixed position that matches the conductive wires within cable 800′ (i.e. a position with two plates adjacent to each other and one plate apart, just as the conductive wires in cable 800′ are arranged). The housing may also clamp onto the outside of the cable to hold the plates in place during measurement.

To place the housing prior to measuring the cable voltage, the housing may be clamped onto the cable and adjusted until the plates line up with the desired conductive plates within the cable. This can be accomplished, for example, by a user watching the measurement system's output as the housing is rotated and adjusted into position around the cable.

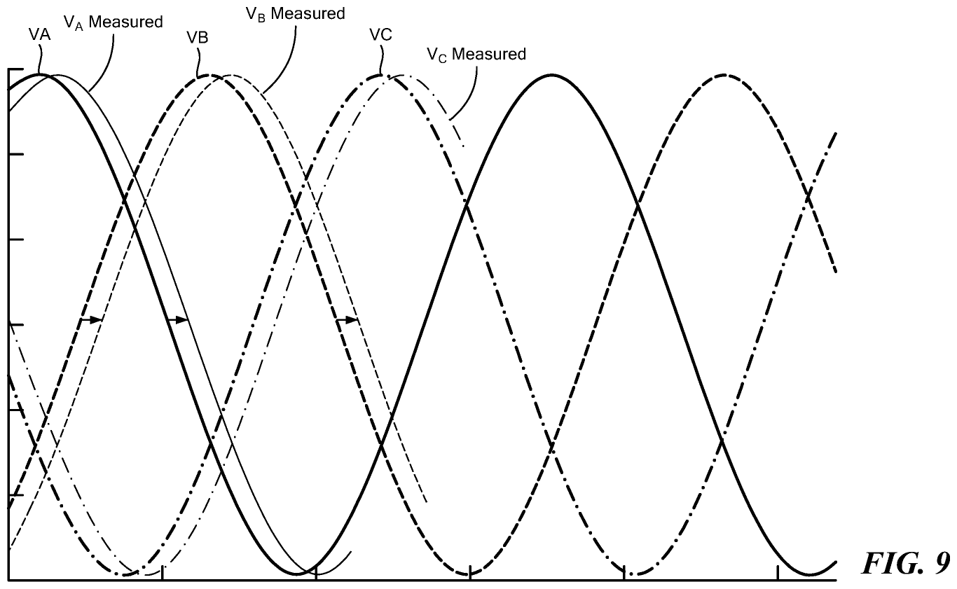

Referring now to FIG. 9, a graph 900 shows line voltages of a three-phase cable 100. In graph 900, the vertical axis represents voltage and the horizontal axis represents time. Waveforms V_{A}, V_{B}, and V_{C} are the actual voltages on conductive wires A, B, and C. Waveforms V_{A} Measured, V_{B} Measured, and V_{C} Measured are the line voltage waveforms, as measured by the non-intrusive line voltage monitoring system(s) described above. The measured waveforms match the actual waveforms so precisely that, in this graph, the measured waveforms have been phase shifted to the right (as indicated by the arrows) so that they are visible. Otherwise, the measured waveforms would be superimposed on top of the actual waveforms and would not be visible in this graph.

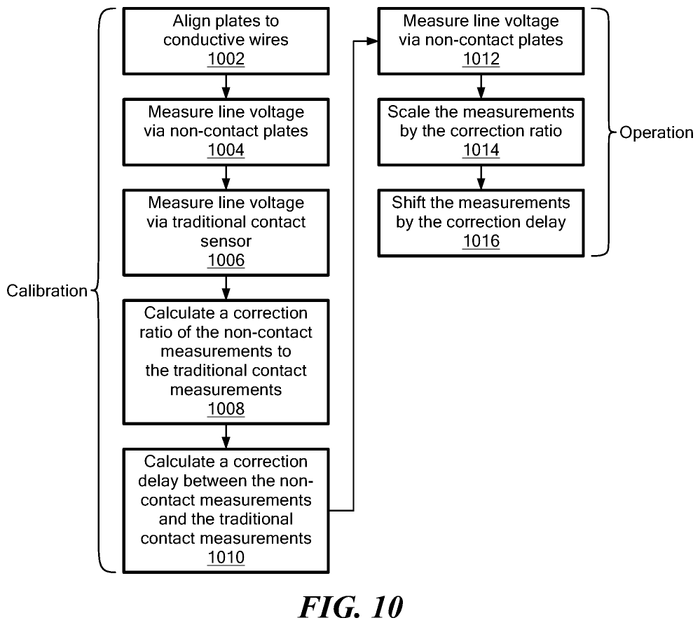

Referring to FIG. 10, a process for calibrating and operating a non-intrusive line voltage monitoring system (e.g. system 200) begins in box 1002 with aligning the plates to the conductive wires within a multi-conductor cable, as described above.

In box 1004, the line voltages are measured and recorded by the non-intrusive line voltage monitoring system.

In box 1006, the line voltages are measured with a traditional contact sensor that directly contacts the conductive wires.

In box 1008, the amplitudes of the voltages measured by the traditional contact sensor are compared with the amplitudes of the voltages measured by the non-intrusive line voltage monitoring system and a correction ratio is calculated. A correction ratio is calculated based on the difference in amplitude of the measured voltages. The correction ration can be applied to the voltages measured by the traditional contact sensor, so they match the amplitudes of the voltages measured by the traditional contact sensor.

In box 1008, the phases of the voltages measured by the traditional contact sensor are compared with the phases of the voltages measured by the non-intrusive line voltage monitoring system and a phase delay is calculated. The phase delay is calculated based on the difference in phases of the measured voltages. The phase delay can be applied to the voltages measured by the traditional contact sensor, so they match the phases of the voltages measured by the traditional contact sensor.

Once calibration is complete, operation of the non-intrusive line voltage monitoring system begins in box 1012 by measuring the line voltages of the conductive wires. In box 1014, the correction ratio is applied to correct the amplitude of the measured line voltages. Finally, in box 1016, the phase delay that was calculated in box 1010 is applied to correct the phase of the measured voltages.

Various embodiments of the concepts, systems, devices, structures, and techniques sought to be protected are described above with reference to the related drawings. Alternative embodiments can be devised without departing from the scope of the concepts, systems, devices, structures, and techniques described. It is noted that various connections and positional relationships (e.g., over, below, adjacent, etc.) may be used to describe elements in the description and drawing. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising, “include,” “includes,” “including,” “has,” “having,” “contains” or “containing,” or any other variation are intended to cover a non-exclusive inclusion. For example, an apparatus, a method, a composition, a mixture or an article, that comprises a list of elements is not necessarily limited to only those elements but can include other elements not expressly listed or inherent to such apparatus, method, composition, mixture, or article.

Additionally, the term “exemplary” is means “serving as an example, instance, or illustration. Any embodiment or design described as “exemplary” is not necessarily to be construed as preferred or advantageous over other embodiments or designs. The terms “one or more” and “at least one” indicate any integer number greater than or equal to one, i.e. one, two, three, four, etc. The term “plurality” indicates any integer number greater than one. The term “connection” can include an indirect “connection” and a direct “connection”.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it may affect such feature, structure, or characteristic in other embodiments whether or not explicitly described.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and carried out in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

1. A system for non-intrusive line voltage monitoring of a cable with multiple conductors, the system comprising:
a plurality of conductive plates, each conductive plate configured to be positioned adjacent to an electrical conductor within the polyphase cable to maximize a capacitive coupling between the electrical conductor and the respective plate and minimize a capacitive coupling other electrical conductors in the polyphase and the respective plate;
the overall arrangement of conductive plates and conductors arranged to maximize capacitive coupling between each plate and its associated conductor while minimizing coupling between each plate and other conductors
a circuit configured to determine the voltage of at least one of the electrical conductors by measuring currents flowing between at least two of the conductive plates.

2. The system of claim 1 wherein the cable is a three-phase cable and the plurality of conductive plates comprises:
a first conductive plate configured to be positioned adjacent to a first electrical line in the cable to form a first capacitive coupling between the first capacitive plate and the first electrical line;
a second conductive plate configured to be positioned adjacent to a second electrical line in the cable to form a second capacitive coupling between the second capacitive plate and the second electrical line; and
a third conductive plate configured to be positioned adjacent to a third electrical line in the cable to form a third capacitive coupling between the third capacitive plate and the third electrical line;

3. The system of claim 2 wherein the circuit is configured to measure a first current between the first conductive plate and the second conductive plate, a second current between the second conductive plate and the third conductive plate, and a third current between the third conductive plate and the first conductive plate.

4. The system of claim 1 wherein the circuit comprises a fully differential transimpedance amplifier.

5. The system of claim 4 wherein the circuit includes an instrumentation amplifier coupled to an output of the fully differential transimpedance amplifier [to convert the differential output signal to a single-ended voltage signal].

6. The system of claim 1 wherein the circuit includes at least one gain buffer to limit the effect of input bias current.

7. The system of claim 1 further comprising a data acquisition and analysis circuit coupled to the circuit and configured to receive current measurements from the three-phase voltage sensor.

8. The system of claim 7 wherein the data acquisition and analysis circuit is configured to isolate capacitive couplings between at least one first capacitive plate of the plurality of capacitive plates and an electrical conductor adjacent to the first capacitive plate.

9. A method for non-intrusive line voltage monitoring of a polyphase cable, the method comprising:
positioning a plurality of conductive plates around the polyphase cable, each conductive plate placed adjacent to an electrical conductor within the polyphase cable to maximize a capacitive coupling between a respective conductive plate and a closest electrical conductor and minimize a capacitive coupling between the respective conductive plate and other electrical conductors within the polyphase cable;
measuring, by a current measurement circuit, currents flowing between pairs of the conductive plates; and
calculating a line voltage for each electrical conductor within the polyphase cable based on the currents flowing between the pairs of the conductive plates.

10. The method of claim 9 wherein the cable is a three-phase power cable and the plurality of conductive plates comprises a first conductive plate, a second conductive plate, and a third conductive plate.

11. The method of claim 10 further comprising:
positioning the first conductive plate configured adjacent to a first electrical line in the cable to form a first capacitive coupling between the first capacitive plate and the first electrical line;
positioning the second conductive plate adjacent to a second electrical line in the cable to form a second capacitive coupling between the second capacitive plate and the second electrical line;
positioning the third conductive plate adjacent to a third electrical line in the cable to form a third capacitive coupling between the third capacitive plate and the third electrical line;
measuring, by the circuit, currents flowing between the first, second, and third conductive plates.

12. The method of claim 11 wherein measuring the currents comprises measuring a first current between a first conductive plate and a second conductive plate of the plurality of, measuring a second current between the second conductive plate and the third conductive plate, and measuring a third current between the third conductive plate and the first conductive plate.

13. The method of claim 9 wherein the circuit comprises a fully differential transimpedance amplifier.

14. The method of claim 13 wherein the circuit comprises an instrumentation amplifier coupled to an output of the fully differential amplifier to convert the differential output signal to a single-ended voltage signal.

15. The method of claim 9 wherein the circuit includes at least one gain buffer to limit the effect of input bias current.

16. The method of claim 9 wherein the is configured to isolate current signals related to the maximized capacitive couplings.

17. The method of claim 13 wherein the polyphase cable is a three-phase cable.
